(19) United States
(12) Patent Application Publication
(10) Pub. No.: US 2025/0346827 A1
(43) Pub. Date: Nov. 13, 2025

(54) COMPOSITION, CLEANING METHOD OF SEMICONDUCTOR SUBSTRATE, AND METHOD FOR MANUFACTURING ELECTRONIC DEVICE

(71) Applicant: FUJIFILM Corporation, Tokyo (JP)

(72) Inventor: Hanae MATSUMOTO, Haibara-gun (JP)

(73) Assignee: FUJIFILM Corporation, Tokyo (JP)

(21) Appl. No.: 19/276,835

(22) Filed: Jul. 22, 2025

Related U.S. Application Data
(63) Continuation of application No. PCT/JP2024/004007, filed on Feb. 7, 2024.

(30) Foreign Application Priority Data
Mar. 8, 2023 (JP) 2023-035871

(51) Int. Cl. C11D 1/62; C11D 3/20; C11D 3/30; C11D 3/33; H01L 21/02

(52) U.S. Cl. CPC C11D 1/62; C11D 3/2082; C11D 3/2086; C11D 3/30; C11D 3/33; H01L 21/02074

(57) ABSTRACT

An object is to provide a composition having excellent corrosion inhibition properties for copper and excellent cleanability for residues in a case of being applied for cleaning a semiconductor substrate containing a copper-containing substance. The composition of the present invention is a composition for cleaning a semiconductor substrate, the composition containing a compound represented by Formula (1), a compound represented by Formula (2), a polycarboxylic acid, and water.

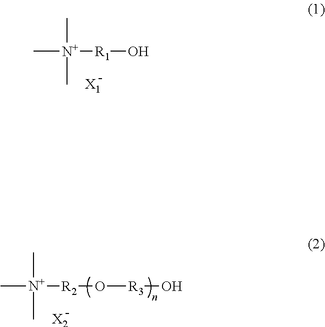

### CROSS-REFERENCE TO RELATED APPLICATIONS

This application is a Continuation of PCT International Application No. PCT/JP2024/004007 filed on Feb. 7, 2024, which claims priority under 35 U.S.C. § 119(a) to Japanese Patent Application No. 2023-035871 filed on Mar. 8, 2023. The above applications are hereby expressly incorporated by reference, in their entirety, into the present application.

### BACKGROUND OF THE INVENTION

### 1. Field of the Invention

The present invention relates to a composition, a cleaning method of a semiconductor substrate, and a method for manufacturing an electronic device.

### 2. Description of the Related Art

In the field of semiconductors, with remarkable increase in integration and performance, even a very small amount of impurities (contaminants) and/or attachments (particles) has a great influence on the performance of an apparatus and eventually the yield of a product.

In each manufacturing step of a semiconductor element, various contaminants and particles (hereinafter, also referred to as residues) may be generated. In order to remove such residues, in the manufacture of the semiconductor, a cleaning step of a semiconductor substrate is appropriately performed.

For example, as one step of manufacturing the semiconductor element, a chemical mechanical polishing treatment of flattening a surface of a semiconductor substrate having a metal wire film, a barrier metal, an insulating film, and the like using a polishing slurry containing abrasive particles (for example, silica, alumina, and the like) may be performed. In the chemical mechanical polishing treatment, the abrasive particles to be used in the chemical mechanical polishing treatment, a polished wiring line metal film, and/or a metal component derived from the barrier metal or the like and a component such as organic substances contained in the polishing slurry easily remain on the surface of the semiconductor substrate after polishing. Therefore, a cleaning step of cleaning the semiconductor substrate using a composition for cleaning is generally performed after the chemical mechanical polishing treatment.

As the above-described composition, for example, JP2004-048039A discloses an aqueous solution containing 0.84% to 3.2% by mass of choline, 1.5% to 3.8% by mass of 2-(2-hydroxyethoxy)ethyltrimethylammonium hydroxide, 0.05% to 1.0% by mass of 2-[2-(2-hydroxyethoxy)ethoxy]ethyltrimethylammonium hydroxide, and 0.74% to 3.60% by mass of polyethylene glycol.

### SUMMARY OF THE INVENTION

The present inventors have applied the aqueous solution disclosed in JP2004-048039A for cleaning a semiconductor substrate containing a copper-containing substance, and have found that it is not possible to achieve both corrosion inhibition properties for copper and cleanability for residues, and further improvement is required.

Therefore, an object of the present invention is to provide a composition having excellent corrosion inhibition properties for copper and excellent cleanability for residues in a case of being applied for cleaning a semiconductor substrate containing a copper-containing substance.

Another object of the present invention is to provide a cleaning method of a semiconductor substrate and a method for manufacturing an electronic device, using the above-described composition.

As a result of conducting an extensive investigation to achieve the objects, the present inventors have found that the objects can be achieved by the following constitution.
[1] A composition for cleaning a semiconductor substrate, the composition comprising:
a compound represented by Formula (1) described later;
a compound represented by Formula (2) described later;
a polycarboxylic acid; and
water.
[2] The composition according to [1],
in which the polycarboxylic acid includes at least one compound selected from the group consisting of tartaric acid, oxalic acid, malonic acid, phthalic acid, terephthalic acid, isophthalic acid, trimellitic acid, and diethylenetriamine-N,N,N′,N″,N″-pentaacetic acid.
[3] The composition according to [1] or [2], further comprising:
trimethylamine.
[4] The composition according to any one of [1] to [3], further comprising:
alkanolamine.
[5] The composition according to any one of [1] to [4],
in which R₁ in Formula (1) is an ethylene group.
[6] The composition according to any one of [1] to [5],
in which the composition contains at least two kinds of the compounds represented by Formula (2).
[7] The composition according to any one of [1] to [6],
in which R₂ and R₃ in Formula (2) are ethylene groups.
[8] The composition according to any one of [1] to [7],
in which a mass ratio of a content of the compound represented by Formula (1) to a content of the polycarboxylic acid is 30.0 to 150.0.
[9] The composition according to any one of [1] to [8],
in which a mass ratio of a content of the compound represented by Formula (2) to a content of the polycarboxylic acid is 3.0 to 15.0.
[10] The composition according to any one of [1] to [9],
in which a mass ratio of a content of the compound represented by Formula (2) to a content of the compound represented by Formula (1) is 0.08 to 0.20.
[11] The composition according to any one of [1] to [10],
in which a pH is 10.0 to 14.0.
[12] The composition according to any one of [1] to [11],
in which the semiconductor substrate is a semiconductor substrate containing a copper-containing substance, which has been subjected to a chemical mechanical polishing treatment.
[13] A cleaning method of a semiconductor substrate, comprising:
cleaning a semiconductor substrate containing a copper-containing substance, which has been subjected to a chemical mechanical polishing treatment, with the composition according to any one of [1] to [12].
[14] A method for manufacturing an electronic device, comprising:
the cleaning method of a semiconductor substrate according to [13].

According to the present invention, it is possible to provide a composition having excellent corrosion inhibition properties for copper and excellent cleanability for residues in a case of being applied for cleaning a semiconductor substrate containing a copper-containing substance.

In addition, according to the present invention, it is also possible to provide a cleaning method of a semiconductor substrate and a method for manufacturing an electronic device, using the above-described composition.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, numerical ranges represented by “to” include numerical values before and after “to” as lower limit values and upper limit values.

In the present specification, “total mass of components in the composition excluding a solvent” means the total mass of all components contained in the composition, other than a solvent such as water and an organic solvent.

In the present specification, in a case where there are two or more components corresponding to a certain component, “content” of such a component means the total content of the two or more components.

Unless otherwise specified, compounds described in the present specification may include structural isomers, optical isomers, and isotopes. In addition, one kind of structural isomer, optical isomer, and isotope may be included, or two or more kinds thereof may be included.

In the present specification, in a case of a plurality of substituents, linking groups, and the like (hereinafter, referred to as a substituent and the like) represented by specific reference numeral, or in a case of simultaneously defining a plurality of the substituent and the like, it means that each of the substituent and the like may be the same as or different with each other. The same applies to the definition of the number of substituents and the like.

A bonding direction of divalent groups cited in the present specification is not limited unless otherwise specified. For example, in a case where Y in a compound represented by Formula “X—Y—Z” is —COO—, Y may be —CO—O— or —O—CO—. In addition, the above-described compound may be “X—CO—O—Z” or “X—O—CO—Z”.

In the present specification, “ppm” means “parts-per-million (10⁻⁶)”, “ppb” means “parts-per-billion (10⁻⁹)”, “ppt” means “parts-per-trillion (10⁻¹²)”.

In the present specification, “weight-average molecular weight” means a weight-average molecular weight in terms of polyethylene glycol measured by gel permeation chromatography (GPC).

In the present specification, 1 angstrom (A) corresponds to 0.1 nm.

### [Composition]

Hereinafter, the composition according to the embodiment of the present invention will be described in detail.

The composition according to the embodiment of the present invention (hereinafter, also simply referred to as “present composition”) contains a compound represented by Formula (1) described later, a compound represented by Formula (2) described later, a polycarboxylic acid, and water.

The reason why the composition having the above-described configuration can achieve the object of the present invention is not necessarily clear, but the present inventors speculate as follows.

The mechanism by which the effect is obtained is not limited by the following supposition. In other words, even in a case where an effect is obtained by a mechanism other than the following, it is included in the scope of the present invention.

In the composition according to the embodiment of the present invention, the compound represented by Formula (1) and the compound represented by Formula (2), which is easily adsorbed to residues and has excellent residue removability, act synergistically to exhibit excellent cleanability for residues. The above-described compounds have corrosiveness to a copper-containing substance, but the present composition further contains a polycarboxylic acid which protects a surface of the copper-containing substance by being adsorbed to the surface of the copper-containing substance with a polyfunctional carboxy group as an action point, and suppresses corrosion without impairing the cleanability of the above-described compounds, and thus the present composition also has excellent corrosion inhibition properties for copper. As a result, in a case of being used for cleaning a semiconductor substrate containing a copper-containing substance, both the corrosion inhibition properties for copper and the cleanability for residues can be achieved.

Hereinafter, the fact that, in a case of being used for cleaning a semiconductor substrate containing a copper-containing substance, at least one of the corrosion inhibition properties for copper or the cleanability for residues is more excellent is also referred to as “effect of the present invention is more excellent”.

[Compound Represented by Formula (1) (Compound (1))]

The present composition contains a compound represented by Formula (1) (compound (1)).

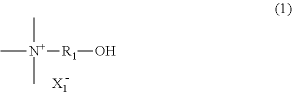

In Formula (1), R₁ represents an alkylene group which may have a substituent.

The above-described alkylene group may be linear, branched, or cyclic, and is preferably linear or branched, and more preferably linear.

The number of carbon atoms in the above-described alkylene group is preferably 1 to 8, more preferably 1 to 5, and still more preferably 2 or 3.

Examples of the above-described alkylene group include a methylene group, an ethylene group, a propylene group, a 1-methylethylene group, a 2-methylethylene group, a butylene group, a pentylene group, and a hexylene group; and an ethylene group, a propylene group, or a 2-methylethylene group is preferable, and an ethylene group is more preferable.

The above-described alkylene group may further have a substituent. Examples of the substituent which may be included in the above-described alkylene group include a halogen atom such as a fluorine atom, a chlorine atom, and a bromine atom; an alkoxy group; a hydroxy group; an alkoxycarbonyl group such as a methoxycarbonyl group and an ethoxycarbonyl group; an acyl group such as an acetyl group, a propionyl group, and a benzoyl group; a cyano group; and a nitro group. Among these, a halogen atom or a hydroxy group is preferable.

It is also preferable that the above-described alkylene group does not have a substituent.

In Formula (1), X₁⁻ represents a monovalent anion.

Examples of the above-described anion include an acid anion such as a carboxylate ion and a nitrate ion; a hydroxide ion; and a halide ion such as a chloride ion, a fluoride ion, a bromide ion, and an iodide ion. Among these, a hydroxide ion is preferable.

The compound (1) may be ionized in the present composition.

Examples of the compound represented by Formula (1) include 2-hydroxyethyltrimethylammonium hydroxide (choline), 2-hydroxyethyltrimethylammonium chloride, 2-hydroxypropyltrimethylammonium hydroxide (2-methylcholine), and 2-hydroxypropyltrimethylammonium chloride; and choline is preferable.

The compound (1) may be used alone, or two or more types thereof may be used in combination.

From the viewpoint that the effect of the present invention is more excellent, a content of the compound (1) is preferably 0.001% to 20.0% by mass, more preferably 0.01% to 5.0% by mass, and still more preferably 0.03% to 0.15% by mass with respect to the total mass of the present composition.

From the viewpoint that the effect of the present invention is more excellent, the content of the compound (1) is preferably 15.0% to 90.0% by mass, more preferably 25.0% to 80.0% by mass, and still more preferably 35.0% to 70.0% by mass with respect to the total mass of components in the present composition excluding a solvent.

### [Compound Represented by Formula (2) (Compound (2))]

The present composition contains a compound represented by Formula (2) (compound (2)).

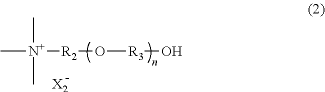

In Formula (2), R₂ and R₃ each independently represent an alkylene group which may have a substituent.

The above-described alkylene group may be linear, branched, or cyclic, and is preferably linear or branched, and more preferably linear.

The number of carbon atoms in the above-described alkylene group is preferably 1 to 8, more preferably 1 to 5, and still more preferably 2 or 3.

Examples of the above-described alkylene group include a methylene group, an ethylene group, a propylene group, a 1-methylethylene group, a 2-methylethylene group, a butylene group, a pentylene group, and a hexylene group; and an ethylene group, a propylene group, or a 2-methylethylene group is preferable, and an ethylene group is more preferable.

The above-described alkylene group may further have a substituent. Examples of the substituent which may be included in the above-described alkylene group include a halogen atom such as a fluorine atom, a chlorine atom, and a bromine atom; an alkoxy group; a hydroxy group; an alkoxycarbonyl group such as a methoxycarbonyl group and an ethoxycarbonyl group; an acyl group such as an acetyl group, a propionyl group, and a benzoyl group; a cyano group; and a nitro group. Among these, a halogen atom or a hydroxy group is preferable.

It is also preferable that the above-described alkylene group does not have a substituent.

In a case where a plurality of R₃'s are present, groups represented by the plurality of R₃'s may be the same or different from each other; but it is preferable to be the same, and it is more preferable that all R₃'s are ethylene groups.

In Formula (2), n represents an integer of 1 or more.
n is preferably an integer of 1 to 8, more preferably an integer of 1 to 4, and still more preferably 1 or 2.

In Formula (2), X₂⁻ represents a monovalent anion.

Examples of the above-described anion include an acid anion such as a carboxylate ion and a nitrate ion; a hydroxide ion; and a halide ion such as a chloride ion, a fluoride ion, a bromide ion, and an iodide ion. Among these, a hydroxide ion is preferable.

The compound (2) may be ionized in the present composition.

Examples of the compound (2) include compounds shown below, and a compound A or a compound B is preferable. X⁻ represents a monovalent anion.

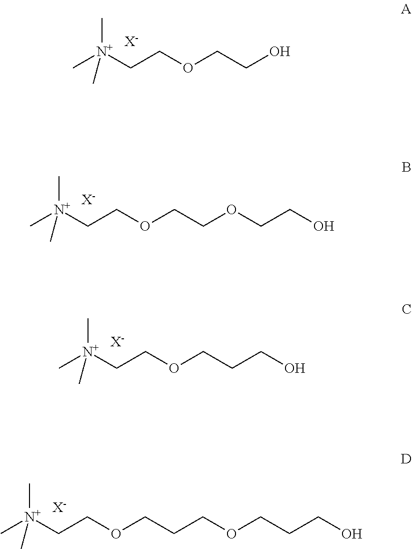

The compound (2) may be used alone, or two or more types thereof may be used in combination.

From the viewpoint that the cleanability for residues is more excellent, the present composition preferably contains two or more kinds of the compounds (2), and more preferably contains two or more kinds of the compounds (2) having different n's.

From the viewpoint that the effect of the present invention is more excellent, a content of the compound (2) is preferably 0.0001% to 5.0% by mass, more preferably 0.001% to 0.5% by mass, and still more preferably 0.005% to 0.015% by mass with respect to the total mass of the present composition.

From the viewpoint that the effect of the present invention is more excellent, the content of the compound (2) is preferably 0.1% to 30.0% by mass, more preferably 1.0% to 15.0% by mass, and still more preferably 5.0% to 8.0% by mass with respect to the total mass of components in the present composition excluding a solvent.

From the viewpoint that the effect of the present invention is more excellent, a mass ratio of the content of the compound (2) to the content of the compound (1) is preferably 0.01 to 1.00, more preferably 0.02 to 0.50, and still more preferably 0.08 to 0.20.

### [Polycarboxylic Acid]

The present composition contains a polycarboxylic acid.

The polycarboxylic acid is an organic compound having at least two or more carboxy groups in a molecule.

The upper limit of the number of carboxy groups in the polycarboxylic acid is not particularly limited as long as it is 2 or more; and it is preferably 2 to 12, more preferably 2 to 8, and still more preferably 2 to 6.

A molecular weight of the polycarboxylic acid is preferably 800 or less, more preferably 600 or less, and still more preferably 450 or less. The lower limit thereof is preferably 90 or more.

The number of carbon atoms in the polycarboxylic acid is preferably 2 to 30 and more preferably 2 to 20.

The polycarboxylic acid may have a heteroatom other than the atom constituting the carboxy group in the polycarboxylic acid. Examples of the heteroatom include an oxygen atom, a nitrogen atom, and a sulfur atom.

The polycarboxylic acid may further have a substituent other than the carboxy group. Examples of the substituent include a halogen atom, an amino group, a hydroxy group, a cyano group, and a nitro group; and an amino group or a hydroxy group is preferable, and a hydroxy group is more preferable.

Specific examples of the polycarboxylic acid include aliphatic polycarboxylic acids such as tartaric acid, oxalic acid, malonic acid, succinic acid, citric acid, maleic acid, malic acid, glutaric acid, adipic acid, pimelic acid, and sebacic acid; aromatic polycarboxylic acids such as phthalic acid, terephthalic acid, isophthalic acid, and trimellitic acid; and amino polycarboxylic acids such as diethylenetriaminepentaacetic acid (DTPA), butylenediaminetetraacetic acid, ethylenediaminetetrapropionic acid, triethylenetetraminehexaacetic acid, 1,3-diamino-2-hydroxypropane-N,N,N′,N′-tetraacetic acid, propylenediaminetetraacetic acid, ethylenediaminetetraacetic acid (EDTA), trans-1,2-diaminocyclohexanetetraacetic acid, ethylenediaminediacetic acid, ethylenediaminedipropionic acid, 1,6-hexamethylene-diamine-N,N,N′,N′-tetraacetic acid, N,N-bis(2-hydroxybenzyl)ethylenediamine-N,N-diacetic acid, diaminopropanetetraacetic acid, 1,4,7,10-tetraazacyclododecane-tetraacetic acid, diaminopropanetetraacetic acid, and (hydroxyethyl)ethylenediaminetriacetic acid.

Among these, tartaric acid, oxalic acid, malonic acid, phthalic acid, terephthalic acid, isophthalic acid, trimellitic acid, or DTPA is preferable, and tartaric acid, oxalic acid, malonic acid, or DTPA is more preferable.

The polycarboxylic acid may be used alone, or two or more types thereof may be used in combination.

From the viewpoint that the effect of the present invention is more excellent, a content of the polycarboxylic acid is preferably 0.0001% to 3.0% by mass, more preferably 0.0003% to 0.08% by mass, and still more preferably 0.001% to 0.01% by mass with respect to the total mass of the present composition.

From the viewpoint that the effect of the present invention is more excellent, the content of the polycarboxylic acid is preferably 0.01% to 15.0% by mass, more preferably 0.3% to 10.0% by mass, still more preferably 0.5% to 5.0% by mass, and particularly preferably 0.6% to 3.0% by mass with respect to the total mass of components in the present composition excluding a solvent.

From the viewpoint that the cleanability for residues is more excellent, a mass ratio of the content of the compound (1) to the content of the polycarboxylic acid is preferably 10.0 or more and more preferably 30.0 or more. From the viewpoint that the corrosion inhibition properties for copper are more excellent, the upper limit thereof is preferably 300.0 or less, more preferably 200.0 or less, still more preferably 150.0 or less, and particularly preferably 100.0 or less.

From the viewpoint that the cleanability for residues is more excellent, a mass ratio of the content of the compound (2) to the content of the polycarboxylic acid is preferably 1.0 or more and more preferably 3.0 or more. From the viewpoint that the corrosion inhibition properties for copper are more excellent, the upper limit thereof is preferably 40.0 or less, more preferably 20.0 or less, still more preferably 15.0 or less, and particularly preferably 10.0 or less.

### [Water]

The present composition contains water.

The type of the water may be any type of water as long as it does not adversely affect the semiconductor substrate; and distilled water, deionized (DI) water, or pure water (ultrapure water) can be used. The pure water (ultrapure water) is preferable from the viewpoint that it contains almost no impurities and has less influence on a semiconductor substrate in a step of manufacturing the semiconductor substrate.

A content of water may be a remainder of components which can be contained in the present composition.

The content of water is preferably 75% by mass or more, more preferably 85% by mass or more, and still more preferably 90% by mass or more with respect to the total mass of the present composition. From the viewpoint that the effect of the present invention is more excellent, the upper limit thereof is preferably 99.999% by mass or less, more preferably 99.99% by mass or less, and still more preferably 99.95% by mass or less.

The present composition may contain a component other than the compound (1), the compound (2), the polycarboxylic acid, and the water described above. Hereinafter, examples of the component which may be contained in the present composition will be described.

### [Trimethylamine]

From the viewpoint that the cleanability for residues is more excellent, the present composition preferably contains trimethylamine.

From the viewpoint that the corrosion inhibition properties for copper are more excellent, a content of the trimethylamine is preferably 1.0% by mass or less, more preferably 0.1% by mass or less, and still more preferably 0.01% by mass or less with respect to the total mass of the present composition. From the viewpoint that the cleanability for residues is more excellent, the lower limit thereof is preferably 1.0 ppb by mass or more and more preferably 0.01 ppm by mass or more.

From the viewpoint that the corrosion inhibition properties for copper are more excellent, the content of the trimethylamine is preferably 5.0% by mass or less, more preferably 10.0 ppm by mass or less, and still more preferably 5.0 ppm by mass or less with respect to the total mass of components in the present composition excluding a solvent. From the viewpoint that the cleanability for residues is more excellent, the lower limit thereof is preferably 0.05 ppm by mass or more, more preferably 0.1 ppm by mass or more, and still more preferably 0.5 ppm by mass or more.

### [Alkanolamine]

From the viewpoint that the cleanability for residues is more excellent, the present composition preferably contains an alkanolamine. The alkanolamine is a compound different from the above-described polycarboxylic acid.

The alkanolamine is an organic compound having at least one amino group and at least one hydroxy group in the molecule. The above-described amino group may be any of a primary amino group (—NH₂), a secondary amino group (>NH), or a tertiary amino group (>N—).

The number of hydroxy groups in the alkanolamine is 1 or more, preferably 1 to 5 and more preferably 1 to 3.

The number of amino groups in the alkanolamine is 1 or more, preferably 1 to 5 and more preferably 1 to 3.

The alkanolamine may have a substituent other than the hydroxy group and the amino group. Examples of the other substituent include a halogen atom.

Specific examples of the alkanolamine include 2-aminoethanol, monoisopropanolamine (MIPA), methyldiethanolamine (MDEA), 3-amino-1-propanol, trishydroxymethylaminomethane (Tris), 2-amino-2-methyl-1-propanol (AMP), 2-dimethylamino-2-methyl-1-propanol (DMAMP), 2-amino-2-methyl-1,3-propanediol (AMPDO), 2-amino-2-ethyl-1,3-propanediol (AEPDO), 2-amino-1,3-propanediol (2-APDO), 3-amino-1,2-propanediol (3-APDO), 3-methylamino-1,2-propanediol (MAPDO), 2-(methylamino)-2-methyl-1-propanediol (N-MAMP), 2-(aminoethoxy)ethanol (AEE), 2-(2-aminoethylamino)ethanol (AAE), diethanolamine (DEA), triethanolamine (TEA), N-methylethanolamine, N-butylethanolamine, N-cyclohexylethanolamine, 2-(ethylamino)ethanol, propylaminoethanol, diethylene glycol amine (DEGA), N,N′-bis(2-hydroxyethyl)ethylenediamine, 1,2-bis(2-aminoethoxy)ethane, N-tert-butyldiethanolamine, N-butyldiethanolamine, N-methyldiethanolamine, 1-piperidineethanol, and 1-(2-hydroxyethyl)piperazine.

Among these, as the alkanolamine, 2-aminoethanol, MIPA, MDEA, Tris, AMP, DMAMP, 3-amino-1-propanol, or TEA is preferable, and 2-aminoethanol, MIPA, or MDEA is more preferable.

The alkanolamine may be used alone, or two or more types thereof may be used in combination.

From the viewpoint that the effect of the present invention is more excellent, a content of the alkanolamine is preferably 0.001% to 15.0% by mass, more preferably 0.01% to 3.0% by mass, and still more preferably 0.03% to 0.08% by mass with respect to the total mass of the present composition.

From the viewpoint that the effect of the present invention is more excellent, the content of the alkanolamine is preferably 10.0% to 70.0% by mass, more preferably 15.0% to 50.0% by mass, and still more preferably 23.0% to 40.0% by mass with respect to the total mass of components in the present composition excluding a solvent.

From the viewpoint that the effect of the present invention is more excellent, a mass ratio of the content of the alkanolamine to the content of the compound (1) is preferably 0.01 to 10.0, more preferably 0.1 to 3.0, and still more preferably 0.4 to 1.0.

From the viewpoint that the effect of the present invention is more excellent, a mass ratio of the content of the polycarboxylic acid to the content of the alkanolamine is preferably 0.001 to 1.0, more preferably 0.01 to 0.1, and still more preferably 0.02 to 0.05.

### [Other Components]

In addition to the above-described components, the present composition may contain other components such as an amine compound different from the trimethylamine and the alkanolamine, a chelating agent, an anticorrosion agent, a pH adjuster, a surfactant, an organic solvent, a polymer, a polyhydroxy compound having a molecular weight of 500 or more, and an oxidizing agent. These components are compounds different from the above-described respective components (the compound (1), the compound (2), the polycarboxylic acid, the trimethylamine, and the alkanolamine).

Hereinafter, other components will be described.

### <Other Amine Compounds>

The present composition may contain an amine compound different from the above-described trimethylamine and alkanolamine.

Examples of the other amine compounds include an aliphatic amine having no hydroxy group, other than the trimethylamine.

Examples of the aliphatic amine having no hydroxy group include alkyl monoamines such as methylamine, ethylamine, propylamine, n-butylamine, 3-methoxypropylamine, tert-butylamine, n-hexylamine, n-octylamine, 2-ethylhexylamine, dimethylamine, diethylamine, and triethylamine; alkylene diamines such as ethylenediamine (EDA), 1,3-propanediamine (PDA), 1,2-propanediamine, 1,3-butanediamine, 1,4-butanediamine, and 1,3-bis(dimethylamino)butane; and polyalkyl polyamines such as diethylenetriamine (DETA), triethylenetetramine (TETA), bis(aminopropyl)ethylenediamine (BAPEDA), tetraethylenepentamine, and N,N,N′,N″,N″-pentamethyldiethylenetriamine (PMDETA).

In addition to the above, examples thereof also include an alicyclic amine compound having no hydroxy group, and specific examples thereof include cyclic amidine compounds (compound having a heterocyclic ring including an amidine structure (>N—C═N—) in the ring) such as diazabicycloundecene (1,8-diazabicyclo[5.4.0]undec-7-ene: DBU), diazabicyclononene (1,5-diazabicyclo[4.3.0]non-5-ene: DBN), 3,4,6,7,8,9,10,11-octahydro-2H-pyrimido[1.2-a]azocine, 3,4,6,7,8,9-hexahydro-2H-pyrido[1.2-a]pyrimidine, 2,5,6,7-tetrahydro-3H-pyrrolo[1.2-a]imidazole, 3-ethyl-2,3,4,6,7,8,9,10-octahydropyrimido[1.2-a]azepine, and creatinine; and piperazine compounds such as piperazine, 1-methylpiperazine, 2-methylpiperazine, 1-ethylpiperazine, 1-propylpiperazine, 1-butylpiperazine, 1,4-dimethylpiperazine, 2,5-dimethylpiperazine, 2,6-dimethylpiperazine, 1-phenylpiperazine, N-(2-aminoethyl)piperazine (AEP), 1,4-bis(2-aminoethyl)piperazine (BAEP), 1,4-bis(3-aminopropyl)piperazine (BAPP), and 1,4-diazabicyclo[2.2.2]octane (DABCO).

### <Chelating Agent>

The present composition may contain a chelating agent. As described above, the chelating agent is a compound different from the polycarboxylic acid.

The chelating agent is a compound having a functional group (coordinating group) which can function as a ligand.

Examples of a coordinating group included in the chelating agent include a phosphonic acid group, a carboxy group, and a sulfo group; and a phosphonic acid group is preferable.

Examples of the chelating agent include an organic chelating agent and an inorganic chelating agent.

The organic chelating agent is a chelating agent containing an organic compound, and examples thereof include a phosphonic acid-based chelating agent having a phosphonic acid group as the coordinating group and a carboxylic acid-based chelating agent having a carboxy group as the coordinating group (for example, hydroxymonocarboxylic acid).

Examples of the inorganic chelating agent include a condensed phosphoric acid and a salt thereof.

As the chelating agent, the organic chelating agent is preferable.

The chelating agent preferably has a low molecular weight. Specifically, the molecular weight of the chelating agent is preferably 600 or less, more preferably 450 or less, and still more preferably 300 or less. The lower limit thereof is preferably 50 or more and more preferably 100 or more.

The number of carbon atoms in the chelating agent is preferably 1 to 15 and more preferably 2 to 15.

Examples of the phosphonic acid-based chelating agent include ethylidene diphosphonic acid, 1-hydroxyethylidene-1,1′-diphosphonic acid (HEDPO), 1-hydroxypropyridene-1,1′-diphosphonic acid, and 1-hydroxybutylidene-1,1′-diphosphonic acid, ethylaminobis(methylenephosphonic acid), dodecylaminobis(methylenephosphonic acid), nitrilotris(methylenephosphonic acid) (NTPO), ethylenediaminebis(methylenephosphonic acid) (EDPO), 1,3-propylenediaminebis(methylenephosphonic acid), ethylenediaminetetra(methylenephosphonic acid) (EDTPO), ethylenediaminetetra(ethylenephosphonic acid), 1,3-propylenediaminetetra(methylenephosphonic acid) (PDTMP), 1,2-diaminopropanetetra(methylenephosphonic acid), 1,6-hexamethylenediaminetetra(methylenephosphonic acid), diethylenetriaminepenta(methylenephosphonic acid) (DEPPO), diethylenetriaminepenta(ethylenephosphonic acid), triethylenetetraminehexa(methylenephosphonic acid), and triethylenetetraminehexa(ethylenephosphonic acid); and HEDPO, NTPO, EDTPO, or DEPPO is preferable.

In addition, as the phosphonic acid-based chelating agent, compounds described in paragraphs [0026] to [0036] of WO2018/020878A and compounds ((co)polymers) described in paragraphs [0031] to [0046] of WO2018/030006A can be used, the contents of which are incorporated herein by reference.

The chelating agent may be used alone, or two or more types thereof may be used in combination.

A content of the chelating agent is preferably 0.0001% to 1.0% by mass, more preferably 0.0005% to 0.1% by mass, and still more preferably 0.001% to 0.05% by mass with respect to the total mass of the present composition.

The content of the chelating agent is preferably 0.1% to 30.0% by mass and more preferably 1.0% to 15.0% by mass with respect to the total mass of components in the present composition excluding a solvent.

### <pH Adjuster>

The present composition may contain a pH adjuster for adjusting and maintaining the pH of the composition.

The pH adjuster is a basic compound and an acidic compound, which are different from the above-described compounds which can be contained in the present composition (for example, the compound (1), the compound (2), the polycarboxylic acid, the trimethylamine, and the alkanolamine). However, it is permissible to adjust the pH of the present composition by adjusting the addition amount of each of the above-described components.

The basic compound is a compound which exhibits basicity (pH of more than 7.0) in an aqueous solution, and examples thereof include a basic inorganic compound and a basic organic compound.

Examples of the basic inorganic compound include alkali metal hydroxides such as sodium hydroxide and potassium hydroxide, and alkaline earth metal hydroxides.

Examples of the basic organic compound include a quaternary ammonium compound different from the compound (1) and the compound (2).

Examples of the quaternary ammonium compound different from the compound (1) and the compound (2) include tetraalkylammonium compounds such as tetramethylammonium hydroxide (TMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), and tetrabutylammonium hydroxide (TBAH); and benzyltrimethylammonium hydroxide (BTMAH).

The acidic compound is a compound which exhibits acidity (a pH of less than 7.0) in an aqueous solution.

Examples of the acidic compound include an acidic inorganic compound.

Examples of the acidic inorganic compound include hydrochloric acid, sulfuric acid, nitric acid, nitrous acid, sulfurous acid, phosphoric acid, boric acid, and hexafluorophosphoric acid.

As the acidic compound as the pH adjuster, a salt of the acidic compound may be used as long as it is an acid or an acid ion (anion) in an aqueous solution.

The pH adjuster may be used alone, or two or more types thereof may be used in combination.

A content of the pH adjuster can be selected depending on the type and amount of other components and the target pH of the composition. For example, the content of the pH adjuster is preferably 0.001% to 10% by mass, more preferably 0.01% to 5% by mass, and still more preferably 0.01% to 1% by mass with respect to the total mass of the present composition.

### <Surfactant>

The surfactant is not particularly limited as long as it is a compound having a hydrophilic group and a hydrophobic group (lipophilic group) in one molecule; and examples thereof include a nonionic surfactant and an anionic surfactant.

In many cases, the surfactant has at least one hydrophobic group selected from the group consisting of an aliphatic hydrocarbon group, an aromatic hydrocarbon group, and a group obtained by combining these groups.

The number of carbon atoms in the surfactant is preferably 16 to 100.

Examples of the nonionic surfactant include an ester-type nonionic surfactant, an ether-type nonionic surfactant, and an ester-ether-type nonionic surfactant; and an ether-type nonionic surfactant is preferable.

As the nonionic surfactant, for example, compounds exemplified in paragraph [0126] of WO2022/044893A can also be used, the contents of which are incorporated herein by reference.

Examples of the anionic surfactant include a phosphoric acid ester-based surfactant having a phosphoric acid ester group, a sulfonic acid-based surfactant having a sulfo group, a phosphonic acid-based surfactant having a phosphonic acid group, a sulfuric acid ester-based surfactant having a sulfuric acid ester group, and a carboxylic acid-based surfactant having a carboxy group.

As the anionic surfactant, for example, compounds exemplified in paragraphs [0116] to [0123] of WO2022/044893A can also be used, the contents of which are incorporated herein by reference.

### <Anticorrosion Agent>

The anticorrosion agent is not particularly limited as long as it is a compound having a function of preventing corrosion of an exposed surface of the semiconductor substrate (particularly, a copper-containing substance); and examples thereof include a heterocyclic compound.

As the heterocyclic compound, a nitrogen-containing heterocyclic compound in which at least one of heteroatoms constituting a heterocycle is a nitrogen atom is preferable.

Examples of the nitrogen-containing heterocyclic compound include an azole compound, a purine compound, a pyrrole compound, a pyridine compound, a pyrazine compound, a pyrimidine compound, an indole compound, an indolizine compound, an indazole compound, a quinoline compound, and an oxazole compound; and a purine compound or an azole compound is preferable.

Specifically, as the anticorrosion agent, for example, compounds described in paragraphs [0046] to [0050] of WO2021/166571A can be used, the contents of which are incorporated herein by reference.

### <Organic Solvent>

Examples of the organic solvent include known organic solvents, for example, an alcohol-based solvent, a glycol-based solvent, a glycol ether-based solvent, and a ketone-based solvent.

It is preferable that the organic solvent is mixed with water at an optional ratio.

As the organic solvent, for example, compounds exemplified in paragraphs [0135] to [0140] of WO2022/044893A can be used, the contents of which are incorporated herein by reference.

### <Polymer>

Examples of the polymer include a water-soluble polymer.

The “water-soluble polymer” means a compound having two or more constitutional units linked in a linear or mesh form through a covalent bond, in which a mass of the polymer dissolved in 100 g of water at 20° C. is 0.1 g or more.

As the polymer, water-soluble polymers described in paragraphs [0043] to [0047] of JP2016-171294A can be used, the contents of which are incorporated herein by reference.

<Polyhydroxy Compound Having Molecular Weight of 500 or More>

The polyhydroxy compound having a molecular weight of 500 or more is a compound different from the above-described compounds which can be contained in the present composition.

The above-described polyhydroxy compound is an organic compound having 2 or more (for example, 2 to 200) alcoholic hydroxy groups in one molecule.

A molecular weight (in a case of having a molecular weight distribution, a weight-average molecular weight) of the above-described polyhydroxy compound is 500 or more, preferably 500 to 100,000 and more preferably 500 to 3,000.

As the polyhydroxy compound, compounds exemplified in paragraphs [0101] and [0102] of WO2022/014287A can be used, the contents of which are incorporated herein by reference.

### <Oxidant>

Examples of the oxidant include a peroxide (hydrogen peroxide and the like), a persulfide (for example, a monopersulfide or a dipersulfide), a percarbonate, an acid thereof, and a salt thereof.

Examples of the oxidant also include an oxidative halide (a periodic acid such as iodic acid, metaperiodic acid, and orthoperiodic acid, and salts thereof), a perboric acid, a perboric acid salt, a cerium compound, and a ferricyanide (potassium ferricyanide or the like).

### [Physical Properties of Composition]

<pH>

The present composition may be either alkaline or acidic.

From the viewpoint that the effect of the present invention is more excellent, the pH of the present composition is preferably 8.0 to 14.0, more preferably 9.0 to 14.0, and still more preferably 10.0 to 14.0.

The pH of the present composition can be measured by a method based on JIS Z 8802-1984 using a known pH meter. A measurement temperature of the pH is 25° C.

### <Metal Content>

A content (measured as ion concentration) of all metals (for example, metal elements of Fe, Co, Na, Cu, Mg, Mn, Li, Al, Cr, Ni, Zn, Sn, and Ag) contained as impurities in the present composition is preferably 5 ppm by mass or less, and more preferably 1 ppm by mass or less. It is assumed that, in manufacturing of a cutting-edge semiconductor element, the present composition having even higher purity is required, and thus the metal content is more preferably a value lower than 1 mass ppm, that is, lower than a value of mass ppb order, particularly preferably 100 mass ppb or less, and most preferably less than 10 mass ppb. The lower limit thereof is preferably 0.

Examples of a method for reducing the metal content include performing a purifying treatment such as distillation and filtration using an ion exchange resin or a filter at a stage of raw materials used in the production of the present composition or a stage after the production of the present composition.

Other examples of the method for reducing the metal content include using a container with less elution of impurities, which will be described later, as a container that accommodates the raw material or the produced present composition. In addition, other examples thereof include lining an interior wall of the pipe with a fluororesin to prevent the elution of metal components from a pipe or the like during the production of the present composition.

### <Coarse Particles>

The present composition may contain coarse particles, but it is preferable that a content thereof is low.

The coarse particles mean particles having a diameter (particle size) of 1 m or more, in a case where a shape of the particles is regarded as a sphere.

The coarse particles contained in the present composition correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the present composition, in which those particles are finally present as particles without being dissolved in the present composition.

A content of the coarse particles in the present composition, in terms of content of particles having a particle size of 1 m or more, is preferably 100 or less and more preferably 50 or less per 1 mL of the present composition. The lower limit thereof is preferably 0 or more, and more preferably 0.01 or more per 1 mL of the present composition.

The content of the coarse particles present in the present composition can be measured in a liquid phase by using a commercially available measuring device in a light scattering type liquid particle measuring method using a laser as a light source.

Examples of a method for removing the coarse particles include a purification treatment such as filtering, which will be described later.

### [Production Method]

The present composition can be produced by a known method. Hereinafter, a method for producing the present composition will be described in detail.

### [Liquid Preparation Step]

The present composition can be produced, for example, by mixing the above-described respective components.

Examples of the method for preparing the present composition include a method in which the compound (1), the compound (2), the polycarboxylic acid, and the optional component as necessary are sequentially charged into a container containing purified pure water, the mixture is stirred and mixed, and a pH adjuster is added as necessary to adjust the pH of the mixed solution, thereby preparing the present composition. In addition, in a case where the respective components are charged into the container, the respective components may be charged at once, or may be charged in a divided manner a plurality of times.

As a stirring device and a stirring method used for preparing the present composition, a known device may be used as a stirrer or a disperser. Examples of a stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the respective components in the liquid preparation step of the present composition, a refining treatment described later, and storage of the produced present composition are preferably performed at 40° C. or lower, and more preferably performed at 30° C. or lower. The lower limit thereof is preferably 5° C. or higher and more preferably 10° C. or higher. By preparing, treating, and/or storing the present composition in the above-described temperature range, stable performance can be maintained for a long period of time.

### <Purification>

It is preferable to subject any one or more of the raw materials for preparing the present composition to a purification treatment in advance. Examples of the purification treatment include known methods such as distillation, ion exchange, and filtration (filtering).

Regarding a degree of purification, it is preferable to carry out the purification treatment until the purity of the raw material is 99% by mass or more, and it is more preferable to carry out the purification treatment until the purity of the stock solution is 99.9% by mass or more. The upper limit thereof is preferably 99.9999% by mass or less.

Examples of a method of the purification treatment include a method of passing the raw material through an ion exchange resin, a reverse osmosis membrane (RO membrane), or the like, reprecipitation, distillation of a raw material, and filtering.

The purification treatment may be performed by combining a plurality of the above-described purification methods. For example, the raw materials are subjected to primary purification by passing through an RO membrane, and then subjected to secondary purification by passing through a purification device consisting of a cation-exchange resin, an anion-exchange resin, or a mixed-bed type ion exchange resin.

In addition, the purification treatment may be performed a plurality of times.

The filter which is used for filtering is not particularly limited as long as it has been used in application for filtering and the like in the related art. Examples thereof include filters formed of fluororesins such as polytetrafluoroethylene (PTFE) and tetrafluoroethylene perfluoroalkyl vinyl ether copolymer (PFA), polyamide-based resins such as nylon, polyarylsulfone (PAS), polyolefin resins (including those with a high density and a ultra-high molecular weight) such as polyethylene and polypropylene (PP), or the like. Among these materials, a material selected from the group consisting of polyethylene, polypropylene (including a high-density polypropylene), a fluororesin (including PTFE and PFA), and a polyamide-based resin (including nylon) is preferable; and a filter of the fluororesin is more preferable. By carrying out filtering of the raw materials using a filter formed of these materials, high-polarity foreign matters which are likely to cause defects can be more effectively removed.

### <Container>

The present composition (including an aspect of a diluted composition described later) can be charged into any container to be stored and transported, as long as problems such as corrosiveness do not arise.

In application for a semiconductor, the container is preferably a container which has a high degree of cleanliness inside the container and in which the elution of impurities from an interior wall of an accommodating portion of the container into the each liquid is suppressed. Examples of such a container include various containers commercially available as a container for a semiconductor composition, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, as the container, containers exemplified in paragraphs [0121] to [0124] of WO2022/004217A can also be used, the contents of which are incorporated herein by reference.

The inside of these containers is preferably cleaned before filling the present composition. With regard to a liquid used for the cleaning, the amount of metal impurities in the liquid is preferably reduced. The present composition may be bottled in a container such as a gallon bottle and a coated bottle after the production, and then may be transported and stored.

In order to prevent changes in the components of the present composition during the storage, the inside of the container may be purged with an inert gas (such as nitrogen and argon) having a purity of 99.99995% by volume or more. In particular, a gas with a low moisture content is preferable. In addition, during the transportation and the storage, the temperature may be normal temperature or may be controlled in a range of −20° C. to 20° C. to prevent deterioration.

### <Clean Room>

It is preferable that handlings including production of the present composition, opening and cleaning of the container, and filling of the present composition, treatment analysis, and measurements are all performed in a clean room. It is preferable that the clean room meets the 14644-1 clean room standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### [Dilution Step]

The above-described present composition may be used for cleaning the semiconductor substrate as a composition (diluted composition) which has been diluted after undergoing a dilution step of diluting the present composition with a diluent such as water.

The diluted composition is also an aspect of the composition according to the embodiment of the present invention as long as the requirements of the present invention are satisfied.

It is preferable to subject the diluent which is used in the dilution step to a purification treatment in advance. In addition, it is more preferable that the diluted composition obtained in the dilution step is subjected to a purification treatment.

Examples of the purification treatment include the ion component reducing treatment using the ion exchange resin, the RO membrane, or the like, and the foreign matter removal using filtering, which are described as the purification treatment for the present composition above, and it is preferable to carry out any one of these treatments.

A dilution rate of the present composition in the dilution step may be appropriately adjusted depending on the type and content of each component and the semiconductor substrate which is a target to be cleaned, but the ratio (dilution ratio) of the diluted composition to the present composition before the dilution is preferably 10 to 10,000 times, more preferably 20 to 3,000 times, still more preferably 50 to 1,000 times, and particularly preferably 75 to 150 times in terms of mass ratio or volume ratio (volume ratio at 23° C.).

In addition, from the viewpoint of more excellent defect removability, the present composition is preferably diluted with water (preferably, ultrapure water).

A change in pH before and after the dilution (a difference between the pH of the present composition before the dilution and the pH of the diluted composition) is preferably 2.5 or less, more preferably 2.0 or less, and still more preferably 1.8 or less.

It is preferable that the pH of the present composition before the dilution and the pH of the diluted composition are each in the above-described suitable aspect.

A specific method for the dilution step of diluting the present composition may be performed according to the liquid preparation step of the present composition described above. A stirring device and a stirring method used in the dilution step may also be performed using the known stirring device described in the step of preparing the present composition above.

### [Use Application]

The present composition is used for cleaning a semiconductor substrate, and preferably used for cleaning a semiconductor substrate which has been subjected to a chemical mechanical polishing (CMP) treatment. Hereinafter, a target to be cleaned using the present composition is also referred to as “object to be cleaned”.

Hereinafter, the object to be cleaned with the present composition will be described in detail.

### [Object to be Cleaned]

As described above, the object to be cleaned is a semiconductor substrate, and a semiconductor substrate containing a metal-containing substance is preferable.

In a case where the semiconductor substrate contains a metal-containing substance, for example, the metal-containing substance may be present on any of front and back surfaces, side surfaces, inside of a groove, and the like of the semiconductor substrate. In addition, in a case where the semiconductor substrate contains a metal-containing substance, the metal-containing substance includes not only a case in which the metal-containing substance is directly present on the surface of the semiconductor substrate, but also a case in which the metal-containing substance is present on the semiconductor substrate through another layer.

Examples of a metal contained in the above-described metal-containing substance include at least one metal M selected from the group consisting of copper (Cu), cobalt (Co), ruthenium (Ru), aluminum (Al), tungsten (W), titanium (Ti), tantalum (Ta), chromium (Cr), hafnium (Hf), osmium (Os), platinum (Pt), nickel (Ni), manganese (Mn), iron (Fe), zirconium (Zr), molybdenum (Mo), palladium (Pd), lanthanum (La), niobium (Nb), and iridium (Ir); and at least one metal selected from the group consisting of copper, cobalt, ruthenium, molybdenum, and tungsten is preferable, at least one metal selected from the group consisting of copper and cobalt is more preferable, and copper is still more preferable. That is, the semiconductor substrate as the object to be cleaned preferably contains a copper-containing substance or a cobalt-containing substance, and more preferably contains a copper-containing substance.

The metal-containing substance may be a substance containing a metal atom, and examples thereof include a simple substance of the metal M and an alloy containing the metal M. Among these, the object to be cleaned preferably includes a metal layer containing the metal M as the metal-containing substance; more preferably includes a metal layer containing copper, cobalt, ruthenium, molybdenum, or tungsten; still more preferably includes a metal layer containing copper or cobalt; and particularly preferably includes a metal layer containing copper.

Examples of a metal layer containing Cu (Cu-containing film) include a wire film consisting of only metal copper (copper wire film), and a wire film made of an alloy consisting of metal copper and another metal (a copper alloy wire film).

Examples of a copper alloy wire film include a wire film made of an alloy consisting of at least one metal selected from the group consisting of Al, Ti, Cr, Mn, Ta, Nb, and W, and Cu. More specific examples thereof include a copper-aluminum alloy wire film (CuAl alloy wire film), a copper-titanium alloy wire film (CuTi alloy wire film), a copper-chromium alloy wire film (CuCr alloy wire film), a copper-manganese alloy wire film (CuMn alloy wire film), a copper-tantalum alloy wire film (CuTa alloy wire film), a copper-niobium alloy wire film (CuNb alloy wire film), and a copper-tungsten alloy wire film (CuW alloy wire film).

Examples of a metal layer containing Co (Co-containing film) include a metal film consisting of only metal cobalt (cobalt metal film), and a metal film made of an alloy consisting of metal cobalt and another metal (cobalt alloy metal film).

Examples of a cobalt alloy metal film include a metal film made of an alloy consisting of at least one metal selected from the group consisting of Ti, Cr, Fe, Ni, Mo, Pd, Ta, Nb, and W, and Co. More specific examples thereof include a cobalt-titanium alloy metal film (a CoTi alloy metal film), a cobalt-chromium alloy metal film (a CoCr alloy metal film), a cobalt-iron alloy metal film (a CoFe alloy metal film), a cobalt-nickel alloy metal film (a CoNi alloy metal film), a cobalt-molybdenum alloy metal film (a CoMo alloy metal film), a cobalt-palladium alloy metal film (a CoPd alloy metal film), a cobalt-tantalum alloy metal film (a CoTa alloy metal film), a cobalt-niobium alloy metal film (a CoNb alloy metal film), and a cobalt-tungsten alloy metal film (a CoW alloy metal film).

The object to be cleaned with the present composition may have, for example, a semiconductor substrate, an insulating film, and a barrier metal, in addition to the above-described metal wire film.

Examples of the wafer constituting the semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), antimony (Sb), or the like) and a p-type silicon wafer in which a silicon wafer is doped with a trivalent atom (for example, boron (B), gallium (Ga), or the like). Examples of the silicon of the silicon wafer include amorphous silicon, single crystal silicon, polycrystalline silicon, and polysilicon.

Among these, a wafer consisting of a silicon-based material, such as a silicon wafer, a silicon carbide wafer, and a resin-based wafer (a glass epoxy wafer) including silicon, is preferable.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film, a black diamond (BD) film, and a silicon carbide (SiC) film); and a low-dielectric-constant (Low-k) film is preferable.

Examples of the barrier metal include tantalum (Ta), tantalum nitride (TaN), titanium nitride (TiN), tungsten (W), tungsten alloy (tungsten-titanium (WTi) alloy, tungsten-cobalt (WCo) alloy, and the like), cobalt (Co), cobalt alloy, ruthenium (Ru), and ruthenium alloy.

A method of forming the insulating film, the copper-containing film, the cobalt-containing film, and the like described above on the wafer constituting the semiconductor substrate is not particularly limited as long as it is a method generally performed in this field.

Examples of the method of forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming the copper-containing film and the cobalt-containing film include a method of forming a circuit on the wafer having the above-described insulating film by a known method such as a resist, and then forming the metal layer by a method such as plating, a physical vapor deposition (PVD) method, and a CVD method. The object to be cleaned may have a layer for forming the copper-containing film on the above-described insulating layer.

### <CMP Treatment>

The object to be cleaned is preferably a semiconductor substrate which has been subjected to the CMP treatment; more preferably a semiconductor substrate which contains the metal-containing substance and has been subjected to the CMP treatment; and still more preferably a semiconductor substrate which contains the copper-containing substance and has been subjected to the CMP treatment.

The CMP treatment is a treatment in which a surface of the substrate having a layer selected from the metal wire film, the barrier metal, and the insulating film is flattened by a combined action of a chemical action and a mechanical polishing using a polishing slurry containing abrasive particles (abrasive grains).

A surface of the object to be cleaned, which has been subjected to the CMP treatment, may have residues such as abrasive grains (for example, silica and alumina) used in the CMP treatment, a polished metal wire film, and/or metal impurities (metal residue) derived from the barrier metal. In addition, an organic substance derived from a CMP composition used in the CMP treatment may remain as the residues. For example, since these residues may cause a short-circuit between wiring lines and deteriorate electrical characteristics of the semiconductor substrate, the semiconductor substrate which has been subjected to the CMP treatment is subjected to a cleaning treatment for removing these residues from the surface.

The composition according to the embodiment of the present invention is preferably used as a cleaning liquid for the cleaning treatment after the CMP treatment as described above.

Specific examples of the object to be cleaned, which has been subjected to the CMP treatment, include substrates which have been subjected to the CMP treatment, described in Journal of the Japan Society for Precision Engineering, Vol. 84, No. 3, 2018, but the present invention is not limited thereto.

### <Pad Cleaning Treatment>

The object to be cleaned may be subjected to a pad cleaning treatment after the CMP treatment.

The pad cleaning treatment is a treatment of reducing residues present on the surface of the object to be cleaned using a pad. Specifically, the surface of the object to be cleaned, which has been subjected to the CMP treatment, is brought into contact with the pad, and the object to be cleaned and the pad are relatively slid while supplying a composition for pad cleaning to a contact portion. As a result, the residues on the surface of the object to be cleaned are removed by a frictional force of the pad and the chemical action of the composition for pad cleaning.

The above-described pad is not particularly limited, and can be appropriately selected depending on the type of the object to be cleaned, the type of residues to be removed, and the device to be used. As the pad, for example, a polishing pad used in the CMP treatment may be used, or a buff pad such as a foamed polyurethane-based buff pad, a nonwoven fabric, a suede-based buff pad, and a sponge may be used. The pad cleaning treatment using the pad includes a treatment called buff cleaning or buff polishing.

As the above-described composition for pad cleaning, a known cleaning composition can be used depending on the type of the object to be cleaned and the type and amount of the residues to be removed. Examples of components contained in the composition for pad cleaning include a water-soluble polymer such as polyvinyl alcohol, a dispersion medium such as water, and an acid such as nitric acid. In addition, the composition for pad cleaning does not contain abrasive particles.

The device and conditions used in the pad cleaning treatment can be appropriately selected from known devices and conditions depending on the type of the object to be cleaned and the type and amount of the residues to be removed. For example, a treatment method described in paragraphs [0085] to [0088] of WO2017/169539A can be used, the contents of which are incorporated herein by reference.

In addition, as one embodiment of the pad cleaning treatment, it is also preferable to perform a pad cleaning treatment on the object to be cleaned, using the present composition as the composition for pad cleaning.

The present composition to be subjected to the pad cleaning treatment may be the diluted composition.

The pad cleaning treatment may be performed only once or may be performed twice or more. For example, after the CMP treatment, the object to be cleaned may be subjected to a pad cleaning treatment using a polishing pad and a pad cleaning treatment using a buff pad.

### [Cleaning Method]

The cleaning method of the semiconductor substrate is not particularly limited as long as it includes a cleaning step of cleaning the semiconductor substrate using the present composition, and a known method performed on a CMP-treated semiconductor substrate can be used.

Examples of the cleaning method include a method of bringing the semiconductor substrate into contact with the present composition. The contact method is not particularly limited, and examples thereof include a method of immersing the semiconductor substrate in the present composition placed in a tank, a method of spraying the present composition onto the semiconductor substrate, a method of flowing the present composition onto the semiconductor substrate, and a combination of these methods. The above-described method may be appropriately selected depending on the purpose.

In addition, the above-described method may appropriately adopt a method usually performed in the field. For example, scrub cleaning in which a cleaning member such as a brush is physically brought into contact with a surface of the semiconductor substrate while supplying the present composition to remove residues and the like, spinning (dropping) cleaning in which the present composition is dropped while rotating the semiconductor substrate, or the like may be used. From the viewpoint that impurities remaining on a surface of the semiconductor substrate can be further reduced, it is preferable that the semiconductor substrate immersed in the present composition is subjected to an ultrasonic treatment.

The above-described cleaning step may be performed once or twice or more. In a case of carrying out the cleaning twice or more, the same method may be repeated or different methods may be combined.

The present composition to be subjected to the above-described cleaning step may be the diluted composition.

The cleaning method of the semiconductor substrate may be a single-wafer method or a batch method. The single-wafer method is a method of treating semiconductor substrates one by one, and the batch method is a method of treating a plurality of semiconductor substrates at the same time.

A temperature of the present composition in the cleaning step is not particularly limited, but from the viewpoint of defect removability, it is preferably 10° C. to 60° C., more preferably 15° C. to 50° C., and still more preferably 15° C. to 40° C.

A cleaning time in the cleaning step may be appropriately changed depending on the type, content, and the like of the components which can be contained in the present composition, but is preferably 10 to 120 seconds, more preferably 20 to 90 seconds, and still more preferably 30 to 60 seconds.

A supply amount (supply rate) of the present composition in the cleaning step is preferably 50 to 5,000 mL/min, and more preferably 500 to 2,000 mL/min.

In the cleaning step, a mechanical stirring method may be used in order to further improve the cleaning performance of the present composition. Examples of the mechanical stirring method include a method of circulating the present composition on the semiconductor substrate, a method of flowing or spraying the present composition on the semiconductor substrate, and a method of stirring the present composition with an ultrasonic wave or a megasonic wave.

After the cleaning step, a step of bringing the semiconductor substrate into contact with a rinsing liquid (hereinafter, also referred to as “rinsing step”) may be performed. By performing the rinsing step, the semiconductor substrate obtained in the cleaning step is washed with a rinsing liquid, and the residues can be efficiently removed.

The rinsing step is preferably a step which is performed continuously subsequently after the cleaning step of the semiconductor substrate, in which the semiconductor substrate is rinsed with a rinsing liquid. The rinsing step may be performed using the above-described mechanical stirring method.

Examples of the rinsing liquid include water (preferably, deionized water), methanol, ethanol, isopropyl alcohol (IPA), N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, or the like) may be used.

As a method of bringing the rinsing liquid into contact with the semiconductor substrate, the above-described method of bringing the present composition into contact with the semiconductor substrate can be similarly adopted.

A contact time between the semiconductor substrate and the rinsing liquid can be appropriately changed depending on the type and content of each component contained in the present composition, and the use target and purpose of the present composition. The contact time is practically 10 to 120 seconds, preferably 20 to 90 seconds and more preferably 30 to 60 seconds.

After the above-described rinsing step, a drying step of drying the semiconductor substrate may be performed.

Examples of the drying method include a spin drying method, a method of flowing a dry gas onto the semiconductor substrate, a method of heating the semiconductor substrate by a heating unit such as a hot plate and an infrared lamp, a Marangoni drying method, a Rotagoni drying method, an isopropyl alcohol (IPA) drying method, and a method of combining any of these methods.

### [Method for Manufacturing Semiconductor Device]

The above-described cleaning method can be suitably applied to a method for manufacturing a semiconductor device.

The above-described cleaning method may be performed in combination before or after other steps performed on a substrate. The above-described cleaning method may be incorporated into other steps while performing the cleaning method, or the above-described cleaning method may be incorporated into the other steps.

Examples of the other steps include a step of forming each structure such as a metal wire, a gate structure, a source structure, a drain structure, an insulating film, a ferromagnetic layer, and a non-magnetic layer (for example, layer formation, etching, chemical mechanical polishing, modification, or the like), a resist forming step, an exposure step and a removal step, a heat treatment step, a cleaning step, and an examination step.

The above-described cleaning method may be performed at any stage among the back-end process (BEOL: back end of the line), the middle process (MOL: middle of the line), and the front-end process (FEOL: front end of the line); and it is preferable that the treatment method be performed in a front-end process or a middle process.

### EXAMPLES

Hereinbelow, the present invention will be described in more detail with reference to Examples.

The materials, the amounts and proportions of the materials used, the details of treatments, the procedure of treatments, and the like shown in the following Examples can be appropriately modified as long as the gist of the present invention is maintained. Therefore, the scope of the present invention should not be construed as being limited to Examples shown below.

In Examples, a pH of the composition was measured at 25° C. using a pH meter (manufactured by HORIBA, Ltd., model “F-74”) in accordance with JIS Z 8802-1984.

In addition, in production of compositions of Examples and Comparative Examples, all of handling of a container, and production, filling, storage, and analytical measurement of the compositions were performed in a clean room satisfying a level of ISO Class 2 or lower.

### [Preparation of Composition]

The following compounds were used to produce a composition. As various components used in Examples, those all classified into a semiconductor grade or a high-purity grade equivalent thereto were used.

### [Compound (1)]

Choline (2-hydroxyethyltrimethylammonium hydroxide)
2-Methylcholine (2-hydroxypropyltrimethylammonium hydroxide)

### [Compound (2)]

Compounds A to D shown below

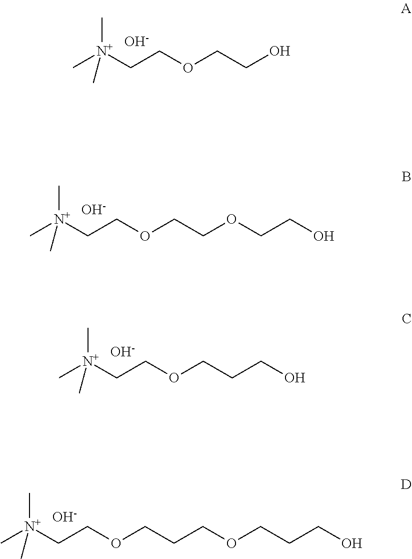

### [Polycarboxylic Acid]

Tartaric acid
Oxalic acid
Malonic acid
Diethylenetriaminepentaacetic acid (DTPA)

### [Other Components]

2-Aminoethanol (alkanolamine)
Monoisopropanolamine (MIPA; alkanolamine)
Methyldiethanolamine (MDEA; alkanolamine)
Trimethylamine
Compound E (refer to the following structural formula)

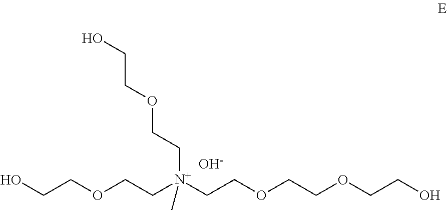

A composition of Example 1 was prepared by the following method. Choline, the compound A, and tartaric acid were mixed with ultrapure water so as to have the formulation shown in Example 1 of Table 1 and Table 2, and the mixture was sufficiently stirred with a stirrer to prepare a concentrated composition. Next, the concentrated composition was diluted with ultrapure water as a diluent at a dilution ratio (100 times; volume ratio) shown in Table 2 to obtain a composition of Example 1.

Compositions of each of Examples and Comparative Examples were prepared according to the preparation method of the composition of Example 1.

The remaining component (remainder) other than components specified as the components of the composition in the tables was ultrapure water.

### [Evaluation of Composition]

Corrosion inhibition properties for copper and cleanability for residues were evaluated for the compositions produced by the above-described method. Hereinafter, the evaluation method will be described.

### [Corrosion Inhibition Properties]

A Cu wafer of 2×2 cm was prepared, placed in a container filled with the composition of each of Examples and Comparative Examples, and immersed at room temperature (25° C.) for 30 minutes. A film thickness of the wafer before and after the immersion was measured using a resistivity meter (VR300DE, manufactured by Kokusai Electric Semiconductor Service Inc.), and an etching rate (A/min) was determined from the difference in film thickness before and after the immersion.

The corrosion inhibition properties for copper were evaluated according to the following evaluation standard. As the above-described etching rate was lower, the corrosion inhibition properties for copper were more excellent. With regard to the corrosion inhibition properties for copper, it is preferable to be evaluated as D or higher.
A: less than 0.65 Å/min
B: 0.65 Å/min or more and less than 0.80 Å/min
C: 0.80 Å/min or more and less than 0.95 Å/min
D: 0.95 Å/min or more and less than 1.20 Å/min
E: 1.20 Å/min or more

### [Cleanability for Residues]

Using FREX300S-II (polishing device, manufactured by EBARA CORPORATION), a wafer (diameter: 12 inches) having a Cu film on a surface was polished under conditions in which a polishing liquid 1 was used as a polishing liquid, an in-plane average value of a polishing pressure was 105 hPa, a supply rate of the polishing liquid was 200 mL/min, and a polishing time was 30 seconds. Next, the wafer subjected to the above-described polishing treatment was polished under conditions in which a polishing liquid 2 was used as a polishing liquid, an in-plane average value of a polishing pressure was 70 hPa, a supply rate of the polishing liquid was 200 mL/min, and a polishing time was 60 seconds.

The obtained wafer subjected to the CMP treatment was subjected to scrub cleaning for 1 minute using a sample of the composition adjusted to room temperature (23° C.), washed with deionized water for 30 seconds, and then subjected to a drying treatment.

Formulations of the polishing liquid 1 and the polishing liquid 2 described above were as follows.

| | | |
|---|---|---|
| Polishing liquid 1 (pH: 7.0) | | |
| Colloidal silica (PL3, manufactured by FUSO | 0.1% | by mass |
| CHEMICAL CO., LTD.) | | |
| Glycine | 1.0% | by mass |
| 3-Amino-1,2,4-triazole | 0.2% | by mass |
| Benzotriazole (BTA) | 30 ppm | by mass |
| Hydrogen peroxide | 1.0% | by mass |
| pH adjuster (ammonia and nitric acid) | | |
| Water remainder | | |
| Polishing liquid 2 (pH: 10.5) | | |
| Colloidal silica (PL3, manufactured by FUSO | 6.0% | by mass |
| CHEMICAL CO., LTD.) | | |
| Citric acid | 1.0% | by mass |
| Alkylalkoxylate surfactant | 100 ppm | by mass |
| BTA | 0.2% | by mass |
| Hydrogen peroxide | 1.0% | by mass |
| pH adjuster (potassium hydroxide and nitric acid) | | |
| Water remainder | | |

A defect detection device (ComPlus-II, manufactured by AMAT) was used to measure the number of detections of signal intensities corresponding to defects having a length of 0.03 μm or more on the obtained polished surface of the wafer. From the number of defects based on the residues on the polished surface of the wafer obtained as described above, the cleanability for residues was evaluated according to the following evaluation standard. As the number of defects detected on the polished surface of the wafer was smaller, the cleanability for residues was better. With regard to the cleanability for residues, it is preferable to be evaluated as D or higher.
A: number of defects per wafer was less than 300.
B: number of defects per wafer was 300 or more and less than 500.
C: number of defects per wafer was 500 or more and less than 700.
D: number of defects per wafer was 700 or more and less than 1,000.
E: number of defects per wafer was 1,000 or more.

### [Result]

The formulation and the evaluation results of the composition of each of Examples and Comparative Examples are shown in Table 1 and Table 2. Table 2 is a continuation of Table 1.

In the tables, the column of “Content (% by mass)” indicates the content (% by mass) of each component with respect to the total mass of the concentrated composition.

In the tables, the column of (1)/(PC) indicates the mass ratio of the content of the compound (1) to the content of the polycarboxylic acid (PC) (Content of compound (1)/Content of polycarboxylic acid).

In the tables, the column of (2)/(PC) indicates the mass ratio of the content of the compound (2) to the content of the polycarboxylic acid (PC) (Content of compound (2)/Content of polycarboxylic acid).

In the tables, the column of (2)/(1) indicates the mass ratio of the content of the compound (2) to the content of the compound (1) (Content of compound (2)/Content of compound (1)).

In the tables, the column of “Dilution ratio (volume ratio)” indicates the dilution rate (volume ratio) of the concentrated composition in a case of preparing the composition as described above.

In the tables, the numerical value in the column of pH indicates the pH of the composition at 25° C., which was measured by the above-described pH meter. The “pH (before dilution)” is the pH of the concentrated composition, and the “pH (after dilution)” is a value measured for a composition prepared by diluting the concentrated composition.

TABLE 1

| | Composition | | | | | | | | | | |
|---|---|---|---|---|---|---|---|---|---|---|---|
| | Compound (1) | | Compound (2) | | | | Polycarboxylic acid (PC) | | | | |
| | | Added | | Added | | Added | | Added | | | |
| | | amount | | amount | | amount | | amount | | | |
| | | (% by | | (% by | | (% by | | (% by | (1)/ | (2)/ | (2)/ |
| | Type | mass) | Type | mass) | Type | mass) | Type | mass) | (PC) | (PC) | (1) |
| Comparative | Choline | 7.67 | | | | | | | | | |
| Example 1 | | | | | | | | | | | |
| Comparative | Choline | 7.67 | | | | | Tartaric acid | 0.10 | | | |
| Example 2 | | | | | | | | | | | |
| Comparative | Choline | 7.67 | Compound A | 0.75 | | | | | | | |
| Example 3 | | | | | | | | | | | |
| Comparative | Choline | 7.67 | | | | | | | | | |
| Example 4 | | | | | | | | | | | |
| Comparative | Choline | 7.67 | Compound A | 0.75 | Compound B | 0.12 | | | | | |
| Example 5 | | | | | | | | | | | |
| Example 1 | Choline | 7.67 | Compound A | 0.75 | | | Tartaric acid | 0.10 | 76.7 | 7.5 | 0.10 |
| Example 2 | Choline | 7.67 | Compound A | 0.75 | Compound B | 0.12 | Tartaric acid | 0.10 | 76.7 | 8.7 | 0.11 |
| Example 3 | Choline | 7.67 | Compound A | 0.75 | Compound B | 0.12 | Tartaric acid | 0.20 | 38.4 | 4.4 | 0.11 |
| Example 4 | 2-Methylcholine | 7.67 | Compound A | 0.75 | Compound B | 0.12 | Tartaric acid | 0.10 | 76.7 | 8.7 | 0.11 |
| Example 5 | Choline | 7.67 | Compound A | 0.75 | Compound B | 0.12 | Oxalic acid | 0.10 | 76.7 | 8.7 | 0.11 |
| Example 6 | Choline | 7.67 | Compound A | 0.75 | Compound B | 0.12 | Malonic acid | 0.10 | 76.7 | 8.7 | 0.11 |
| Example 7 | Choline | 7.67 | Compound A | 0.75 | Compound B | 0.12 | DTPA | 0.10 | 76.7 | 8.7 | 0.11 |
| Example 8 | Choline | 7.67 | Compound A | 0.75 | Compound B | 0.12 | Tartaric acid | 0.10 | 76.7 | 8.7 | 0.11 |
| Example 9 | Choline | 7.67 | Compound A | 0.75 | Compound B | 0.12 | Tartaric acid | 0.10 | 76.7 | 8.7 | 0.11 |
| Example 10 | Choline | 7.67 | Compound A | 0.75 | Compound B | 0.12 | Tartaric acid | 0.10 | 76.7 | 8.7 | 0.11 |
| Example 11 | Choline | 7.67 | Compound A | 0.75 | Compound B | 0.12 | Tartaric acid | 0.10 | 76.7 | 8.7 | 0.11 |
| Example 12 | Choline | 7.67 | Compound A | 0.75 | Compound B | 0.12 | Oxalic acid | 0.10 | 76.7 | 8.7 | 0.11 |
| Example 13 | Choline | 16.00 | Compound A | 0.75 | Compound B | 0.12 | Tartaric acid | 0.10 | 160.0 | 8.7 | 0.05 |
| Example 14 | Choline | 14.00 | Compound A | 0.75 | Compound B | 0.12 | Tartaric acid | 0.10 | 140.0 | 8.7 | 0.06 |
| Example 15 | Choline | 2.50 | Compound A | 0.75 | Compound B | 0.12 | Tartaric acid | 0.10 | 25.0 | 8.7 | 0.35 |
| Example 16 | Choline | 7.67 | Compound A | 1.40 | Compound B | 0.25 | Tartaric acid | 0.10 | 76.7 | 16.5 | 0.22 |
| Example 17 | Choline | 7.67 | Compound A | 0.24 | Compound B | 0.04 | Tartaric acid | 0.10 | 76.7 | 2.8 | 0.04 |
| Example 18 | Choline | 7.67 | Compound A | 0.75 | Compound B | 0.12 | Tartaric acid | 0.03 | 255.7 | 29.0 | 0.11 |
| Example 19 | Choline | 7.67 | Compound A | 0.75 | Compound B | 0.12 | Tartaric acid | 0.50 | 15.3 | 1.7 | 0.11 |
| Example 20 | Choline | 7.67 | Compound A | 0.75 | Compound B | 0.12 | Tartaric acid | 0.10 | 76.7 | 8.7 | 0.11 |
| Example 21 | Choline | 7.67 | Compound A | 0.75 | Compound B | 0.12 | Tartaric acid | 0.10 | 76.7 | 8.7 | 0.11 |
| Example 22 | Choline | 7.67 | Compound A | 0.75 | Compound B | 0.12 | Tartaric acid | 0.10 | 76.7 | 8.7 | 0.11 |
| Example 23 | Choline | 7.67 | Compound C | 0.75 | Compound D | 0.12 | Tartaric acid | 0.10 | 76.7 | 8.7 | 0.11 |
| Example 24 | Choline | 4.52 | Compound A | 0.75 | Compound B | 0.12 | Tartaric acid | 0.10 | 80.2 | 8.7 | 0.11 |
| | 2-Methylcholine | 3.50 | | | | | | | | | |
| Example 25 | Choline | 7.67 | Compound A | 0.75 | Compound B | 0.12 | Tartaric acid | 0.05 | 76.7 | 8.7 | 0.11 |
| | | | | | | | Oxalic acid | 0.05 | | | |
| Example 26 | Choline | 7.67 | Compound A | 0.75 | Compound B | 0.12 | Tartaric acid | 0.10 | 76.7 | 8.7 | 0.11 |
| Example 27 | Choline | 7.67 | Compound A | 0.75 | Compound B | 0.12 | Tartaric acid | 0.10 | 76.7 | 8.7 | 0.11 |
| Example 28 | Choline | 7.67 | Compound A | 0.75 | Compound B | 0.12 | Tartaric acid | 0.10 | 76.7 | 8.7 | 0.11 |

TABLE 2

| | Composition | | | | | | | | | |
|---|---|---|---|---|---|---|---|---|---|---|
| | Alkanolamine | | Trimethylamine | Others | | | | Dilution | | |
| | | Added | Added | | Added | pH | pH | ratio | Corrosion | |
| | | amount (% | amount (% | | amount (% | (before | (after | (volume | inhibition | Clean- |
| | Type | by mass) | by mass) | Type | by mass) | dilution) | dilution) | ratio) | properties | ability |
| Comparative | | | | | | 13.0 | 11.5 | 100 | E | E |
| Example 1 | | | | | | | | | | |
| Comparative | | | | | | 13.0 | 11.5 | 100 | A | E |
| Example 2 | | | | | | | | | | |
| Comparative | | | | | | 13.1 | 11.6 | 100 | E | D |
| Example 3 | | | | | | | | | | |
| Comparative | | | | Compound E | 0.75 | 13.1 | 11.6 | 100 | E | E |
| Example 4 | | | | | | | | | | |
| Comparative | | | | | | 13.1 | 11.6 | 100 | E | C |
| Example 5 | | | | | | | | | | |
| Example 1 | | | | | | 13.1 | 11.6 | 100 | A | C |
| Example 2 | | | | | | 13.1 | 11.6 | 100 | A | C |
| Example 3 | | | | | | 13.1 | 11.6 | 100 | A | C |
| Example 4 | | | | | | 13.1 | 11.6 | 100 | A | C |
| Example 5 | | | | | | 13.1 | 11.6 | 100 | A | C |
| Example 6 | | | | | | 13.1 | 11.6 | 100 | A | C |
| Example 7 | | | | | | 13.1 | 11.6 | 100 | A | C |
| Example 8 | 2-Aminoethanol | 4.5 | | | | 13.3 | 11.8 | 100 | A | B |
| Example 9 | 2-Aminoethanol | 6.0 | | | | 13.8 | 12.1 | 100 | C | A |
| Example 10 | 2-Aminoethanol | 1.5 | | | | 13.0 | 11.5 | 100 | A | C |
| Example 11 | 2-Aminoethanol | 4.5 | 2.5 × 10⁻³ | | | 13.3 | 11.8 | 100 | A | A |
| Example 12 | 2-Aminoethanol | 4.5 | 2.5 × 10⁻³ | | | 13.3 | 11.8 | 100 | A | A |
| Example 13 | 2-Aminoethanol | 4.5 | 2.5 × 10⁻³ | | | 13.9 | 12.1 | 100 | C | A |
| Example 14 | 2-Aminoethanol | 4.5 | 2.5 × 10⁻³ | | | 13.7 | 12.1 | 100 | B | A |
| Example 15 | 2-Aminoethanol | 4.5 | 2.5 × 10⁻³ | | | 12.8 | 11.8 | 100 | A | B |
| Example 16 | 2-Aminoethanol | 4.5 | 2.5 × 10⁻³ | | | 13.4 | 11.9 | 100 | B | A |
| Example 17 | 2-Aminoethanol | 4.5 | 2.5 × 10⁻³ | | | 13.2 | 11.7 | 100 | A | B |
| Example 18 | 2-Aminoethanol | 4.5 | 2.5 × 10⁻³ | | | 13.3 | 11.8 | 100 | D | A |
| Example 19 | 2-Aminoethanol | 4.5 | 2.5 × 10⁻³ | | | 13.1 | 11.6 | 100 | A | B |
| Example 20 | 2-Aminoethanol | 4.5 | 0.5 | | | 13.4 | 11.9 | 100 | B | A |
| Example 21 | MIPA | 4.5 | 2.5 × 10⁻³ | | | 13.3 | 11.8 | 100 | A | A |
| Example 22 | MDEA | 4.5 | 2.5 × 10⁻³ | | | 13.3 | 11.8 | 100 | A | A |
| Example 23 | 2-Aminoethanol | 4.5 | 2.5 × 10⁻³ | | | 13.3 | 11.8 | 100 | A | A |
| Example 24 | 2-Aminoethanol | 4.5 | 2.5 × 10⁻³ | | | 13.2 | 11.7 | 100 | A | A |
| Example 25 | 2-Aminoethanol | 4.5 | 2.5 × 10⁻³ | | | 13.3 | 11.8 | 100 | A | A |
| Example 26 | 2-Aminoethanol | 4.5 | 2.5 × 10⁻³ | | | 13.3 | 13.3 | 1 | C | A |
| Example 27 | 2-Aminoethanol | 4.5 | 2.5 × 10⁻³ | | | 13.3 | 12.3 | 50 | B | A |
| Example 28 | 2-Aminoethanol | 4.5 | 2.5 × 10⁻³ | | | 13.3 | 11.3 | 200 | A | B |

From the results of Tables 1 and 2, it was found that the composition according to the embodiment of the present invention had excellent corrosion inhibition properties for copper and excellent cleanability for residues in a case of being applied for cleaning a semiconductor substrate containing a copper-containing substance.

From the comparison between Example 2 and Example 8, it was found that, in a case where the present composition contained an alkanolamine, the cleanability for residues was more excellent.

From the comparison between Example 8 and Example 11 it was found that, in a case where the present composition contained trimethylamine, the cleanability for residues was more excellent.

From the comparison of Examples 8 to 15, it was found that, in a case where the content of the alkanolamine was 15.0% to 40.0% by mass with respect to the total mass of components in the present composition excluding a solvent, the effect of the present invention was more excellent.

From the comparison between Example 11 and Examples 13 to 15 and Examples 18 and 19, it was found that, in a case where the mass ratio of the content of the compound represented by Formula (1) to the content of the polycarboxylic acid was 30.0 or more, the cleanability for residues was more excellent, in a case of being 200.0 or less, the corrosion inhibition properties for copper were more excellent, and in a case of being 150.0 or less, the corrosion inhibition properties for copper were further excellent.

From the comparison between Example 11 and Examples 16 to 19, it was found that, in a case where the mass ratio of the content of the compound represented by Formula (2) to the content of the polycarboxylic acid was 3.0 or more, the cleanability for residues was more excellent, in a case of being 20.0 or less, the corrosion inhibition properties were more excellent, and in a case of being 15.0 or less, the corrosion inhibition properties for copper were further excellent.

From the comparison between Example 11 and Examples 13 to 17, it was found that, in a case where the mass ratio of the content of the compound represented by Formula (2) to the content of the compound represented by Formula (1) was 0.08 to 0.20, the effect of the present invention was more excellent.

From the comparison between Example 11 and Example 20, it was found that, in a case where the content of trimethylamine was 10.0 ppm by mass or less with respect to the total mass of components in the present composition excluding a solvent, the corrosion inhibition properties for copper were more excellent.

From the comparison between Example 11 and Examples 26 to 28, it was found that, even in a case where the dilution ratio of the present composition varied, the effect of the present invention was excellent; and in a case where the dilution ratio (volume ratio) was 50 times or more, the corrosion inhibition properties were more excellent, and in a case where the dilution ratio was 75 to 150 times, the effect of the present invention was further excellent.

What is claimed is:

1. A composition for cleaning a semiconductor substrate, the composition comprising:
a compound represented by Formula (1);
a compound represented by Formula (2);
a polycarboxylic acid; and
water, 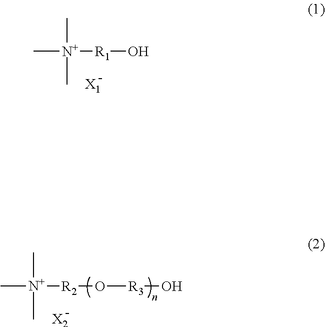
in Formula (1), R₁ represents an alkylene group which may have a substituent, and X₁⁻ represents a monovalent anion,
in Formula (2), R₂ and R₃ each independently represent an alkylene group which may have a substituent, n represents an integer of 1 or more, and X₂⁻ represents a monovalent anion.

2. The composition according to claim 1,
wherein the polycarboxylic acid includes at least one compound selected from the group consisting of tartaric acid, oxalic acid, malonic acid, phthalic acid, terephthalic acid, isophthalic acid, trimellitic acid, and diethylenetriamine-N,N,N′,N″,N″-pentaacetic acid.

3. The composition according to claim 1, further comprising:
trimethylamine.

4. The composition according to claim 1, further comprising:
alkanolamine.

5. The composition according to claim 1,
wherein R₁ in Formula (1) is an ethylene group.

6. The composition according to claim 1,
wherein the composition contains at least two kinds of the compounds represented by Formula (2).

7. The composition according to claim 1,
wherein R₂ and R₃ in Formula (2) are ethylene groups.

8. The composition according to claim 1,
wherein a mass ratio of a content of the compound represented by Formula (1) to a content of the polycarboxylic acid is 30.0 to 150.0.

9. The composition according to claim 1,
wherein a mass ratio of a content of the compound represented by Formula (2) to a content of the polycarboxylic acid is 3.0 to 15.0.

10. The composition according to claim 1,
wherein a mass ratio of a content of the compound represented by Formula (2) to a content of the compound represented by Formula (1) is 0.08 to 0.20.

11. The composition according to claim 1,
wherein a pH is 10.0 to 14.0.

12. The composition according to claim 1,
wherein the semiconductor substrate is a semiconductor substrate containing a copper-containing substance, which has been subjected to a chemical mechanical polishing treatment.

13. A cleaning method of a semiconductor substrate, comprising:
cleaning a semiconductor substrate containing a copper-containing substance, which has been subjected to a chemical mechanical polishing treatment, with the composition according to claim 1.

14. A method for manufacturing an electronic device, comprising:
the cleaning method of a semiconductor substrate according to claim 13.

15. The composition according to claim 2, further comprising:
trimethylamine.

16. The composition according to claim 2, further comprising:
alkanolamine.

17. The composition according to claim 2,
wherein R₁ in Formula (1) is an ethylene group.

18. The composition according to claim 2,
wherein the composition contains at least two kinds of the compounds represented by Formula (2).

19. The composition according to claim 2,
wherein R₂ and R₃ in Formula (2) are ethylene groups.

20. The composition according to claim 2,
wherein a mass ratio of a content of the compound represented by Formula (1) to a content of the polycarboxylic acid is 30.0 to 150.0.
